(19) United States
(12) Patent Application Publication
(10) Pub. No.: US 2021/0410331 A1
(43) Pub. Date: Dec. 30, 2021

(54) INTEGRATED CIRCUIT DIE THERMAL SOLUTIONS WITH A CONTIGUOUSLY INTEGRATED HEAT PIPE

(71) Applicant: Intel Corporation, Santa Clara, CA (US)

(72) Inventors: Feras Eid, Chandler, AZ (US); Adel Elsherbini, Tempe, AZ (US); Georgios Dogiamis, Chandler, AZ (US)

(73) Assignee: Intel Corporation, Santa Clara, CA (US)

(21) Appl. No.: 16/911,817

(22) Filed: Jun. 25, 2020

(51) Int. Cl. H05K 7/20; H05K 3/34

(52) U.S. Cl. CPC H05K 7/20336; H05K 3/34; H05K 7/20481

(57) ABSTRACT

System-level thermal solutions for integrated circuit (IC) die packages including a heat pipe contiguously integrated with base plate material at the hot interface or with heat sink material at the cold interface. Base plate material may be deposited with a high throughput additive manufacturing (HTAM) technique directly upon a surface of the heat pipe to form a base plate suitable for interfacing with an IC die package. The contiguous base plate material may offer low thermal resistance in the absence of any intervening joining material (e.g., solder or brazing filler). Solder or brazing filler may also be eliminated from between a heat sink and a heat pipe by depositing wick material directly upon the heat sink with an HTAM technique. The wick material may be then enclosed by attaching a preformed half-open tube.

### BACKGROUND

Integrated circuit (IC) packaging is a stage of microelectronic device manufacture in which an IC that has been fabricated on a die (or chip) comprising a semiconducting material is encapsulated in an “assembly” or “package” that can protect the IC from physical damage and support electrical contacts that connect the IC to a host circuit board or another package. In the IC industry, the process of fabricating a package is often referred to as packaging, or assembly.

A number of IC die packaging technologies are cooled by a system-level thermal solution that includes a heat pipe to convey heat away from an IC die package and to an external heat sink. FIG. 1A illustrates a partially exploded isometric sectional view of a conventional system-level IC die assembly 101. As shown, assembly 101 includes a system-level thermal solution 150 coupled to an IC die package 110 that is interconnected to a system (printed circuit) board 100. IC die package 110 includes a package substrate 130, which may be any package substrate or a circuit board known and may further include any number of conductive routing layers (not depicted).

Thermal solution 150 is a heat exchanger that includes a heat pipe 155 thermally coupled to a base plate 152. Inside heat pipe 155 there is a wicking material 156, which is to convey a fluid that transfers heat from base plate 152 to a condenser 159 by vaporizing and condensing within heat pipe 155. A thermal interface material (TIM) 115 is between IC die package 110 and base plate 152. TIM 115 may be a preformed “pad” or a viscous polymer, often referred to as “thermal grease.” Base plate 152 is typically made of a high thermal conductivity material (i.e., having a high thermal conductivity coefficient κ with SI units of W m⁻¹ K⁻¹), such as copper. Base plate 152 improves the structural rigidity of thermal solution 150, and helps spread heat laterally beyond the footprint of IC die 120 to increase the effective area of the hot interface of heat pipe 155.

For the conventional architecture illustrated in FIG. 1A, heat pipe 155 is soldered or brazed to base plate 152. However, solder/braze filler 154 through which heat pipe 155 is joined to base plate 152 is often a much worse thermal conductor than either base plate 152 or heat pipe 155. The intervening solder/braze filler 154 may therefore pose a thermal bottleneck in the transfer of heat away from IC die 120.

FIG. 1B illustrates a partially exploded isometric sectional view of another conventional system-level IC die assembly 102. In this example, heat pipe 155 is integrated into a finned heat sink 151. Heat pipe 155 is soldered or brazed within a slot that has been machined into an otherwise planar side of heat sink 151, which is to interface with TIM 115. Solder/braze filler 154 may again be a much worse thermal conductor than either heat sink 151 or heat pipe 155. The intervening solder/braze filler 154 may therefore pose a thermal bottleneck in the transfer of heat away from IC die 120.

Overcoming such thermal bottlenecks to further reduce thermal resistance between IC die and a system-level thermal solution would be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A and 1B illustrate a partially exploded cross-sectional isometric view of an electronic computing device including an IC die and a system-level thermal solution in accordance with conventional assemblies;

FIG. 2 is a flow diagram of methods for forming a heat pipe with a contiguous base plate material suitable for integration into an IC die thermal solution in accordance with some embodiments;

FIG. 3 is a flow diagram of methods for forming a heat sink with contiguous heat pipe wick material suitable for integration into an IC die thermal solution in accordance with some embodiments;

FIGS. 4A, 4B, and 4C illustrate cross-sectional views of an IC die heat exchanger evolving as the methods illustrated in FIG. 2 are practiced in accordance with some embodiments;

FIG. 5 illustrates the deposition of material with a high throughput additive manufacturing (HTAM) technique in accordance with some embodiments;

FIGS. 6A, 7A, 8A, 9A and 10A illustrate a plan view of an IC die heat exchanger evolving as the methods illustrated in FIG. 3 are practiced in accordance with some embodiments;

FIGS. 6B, 7B, 8B, 9B and 10B illustrate a cross-sectional view of the IC die heat exchanger evolving as the methods illustrated in FIG. 3 are practiced in accordance with some embodiments;

FIG. 11A illustrates a cross-sectional view of a system-level IC die assembly in accordance with some mobile device embodiments;

FIG. 11B illustrates a cross-sectional view of a system-level IC die assembly in accordance with some server computer platform embodiments;

FIG. 12 illustrates a mobile electronic computing device and a data server platform employing a thermal solution with a contiguously integrated heat pipe in accordance with some embodiments; and

FIG. 13 is a functional block diagram of an electronic computing device in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive or incompatible.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer disposed over or under another may be directly in contact or may have one or more intervening materials or layers. Moreover, one material or layer disposed between two materials or layers may be directly in contact with the two materials or layers or may have one or more intervening materials or layers. In contrast, a first material or material “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

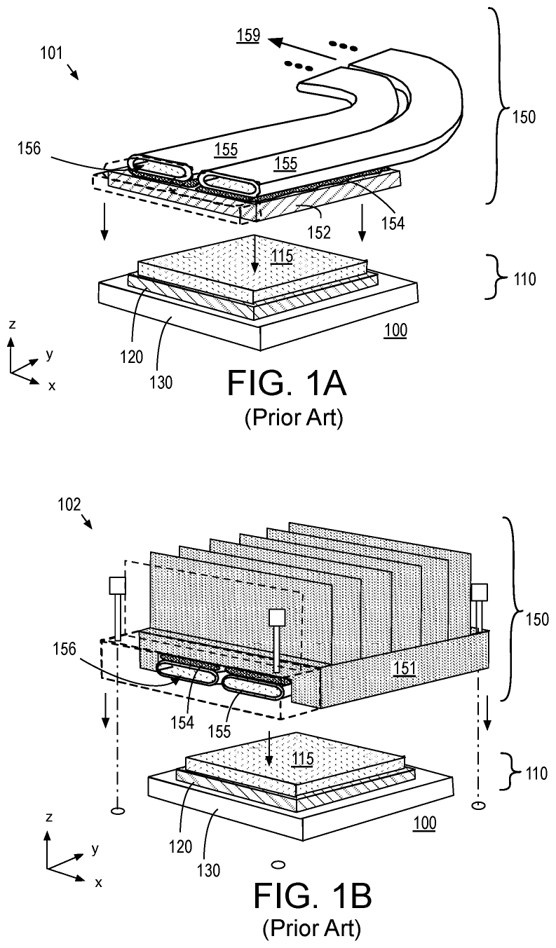

Described herein are examples of a system-level thermal solution including a heat pipe contiguously integrated with a base plate at the hot interface, and/or with a heat sink at the cold interface. As further described in some examples below, base plate material is directly deposited upon a surface of a heat pipe. In some alternative examples, heat pipe wick material is directly deposited upon a surface of a heat sink. Base plate material or heat sink material is therefore contiguously integrated with the heat pipe rather than being joined by an intervening material, such as a solder/braze filler. Hence, in contrast to a conventional heat pipe (e.g., as introduced above in reference to FIG. 1A) that is thermally coupled to a base plate through intervening solder filler, a “contiguous” base plate in accordance with embodiments herein is in direct contact with the heat pipe. Similarly, in contrast to a conventional heat pipe (e.g., as introduced above in reference to FIG. 1B) that is thermally coupled to a heat sink through intervening solder filler, a “contiguous” heat pipe in accordance with embodiments herein is in direct contact with the heat sink. Thermo-mechanical issues attributable to solder/braze filler located within a heat pipe-based thermal solution may therefore be mitigated. For example, thermal resistance associated with the solder/braze filler may be eliminated; reducing the overall thermal resistance and allowing better heat removal and improved IC die performance. Assembly steps and material costs associated with procuring and attaching a discrete base plate and/or attaching a heat sink to a discrete heat pipe may also be avoided.

In accordance with some embodiments, a high throughput additive manufacturing (HTAM) process is employed to form the base plate material upon a surface of a heat pipe. Alternatively, an HTAM process is employed to form at least a wicking material of a heat pipe directly upon a surface of a heat sink or base plate. Hence, an HTAM process may begin with a heat pipe as a starting material and proceed to directly form a base material as a contiguous portion of the heat exchanger, or an HTAM process may being with a heat sink (or base plate) as a starting material and proceed to directly form a heat pipe wick material as a contiguous portion of the heat exchanger. Either of the techniques may reduce the use of solder/braze filler within the heat exchanger and thereby reduce thermal resistance of the thermal solution. The HTAM process may provide very high deposition rates and is suitable for depositing a wide variety of materials having high thermal conductivity. The HTAM process may also deposit materials with controlled levels of porosity and/or surface roughness advantageous for heat pipe wick material.

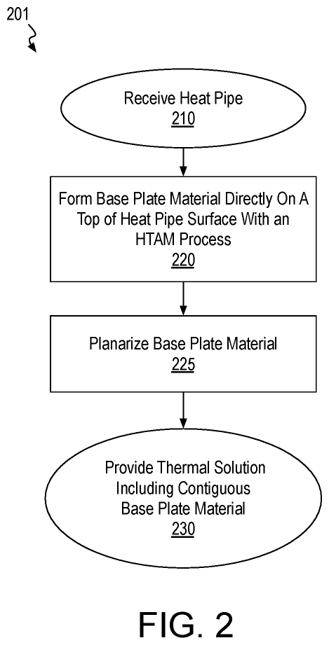

FIG. 2 is a flow diagram of methods 201 for forming a heat pipe with a contiguous base plate material, in accordance with some embodiments. Methods 201 begin with receiving a heat pipe at input 210. Hence, methods 201 may be considered a top-down approach to fabricating an IC die package thermal solution in which the interface to an IC die package is directly formed upon a portion of a prefabricated heat pipe. Methods 201 therefore offer the advantage of beginning with a heat pipe that has desirable performance characteristics, and then building up the hot interface to mate with an IC die.

The heat pipe received at input 210 may be fabricated and/or assembled upstream of methods 201 to any specifications. In exemplary embodiments, the heat pipe is one of one or more pipes that span an area at least as large as a footprint of an IC die to which the heat pipe is to be thermally coupled. The heat pipe(s) may be much larger and/or span longer lengths than the footprint of an IC die package. For example, the heat pipe(s) may have a length that will extend over some portion of the system beyond the IC die package as a means of routing heat through the system to an external heat sink distal from the IC die package. The heat pipe may have any topology, with any cross-sectional profile, such as a substantially circular tube, a flattened tube, or a rectangular/rectilinear tube.

At block 220, a base plate material is deposited over the working surface of the heat pipe that is to become the hot interface to an IC die. The base plate material may be deposited in a substantially uniform manner over some predetermined portion (i.e., length) of the heat pipe(s). For example, a substantially constant thickness of base plate material may be uniformly deposited upon a planar heat pipe surface. Alternatively, base plate material may be deposited upon a heat pipe surface in a non-uniform manner. For example, base plate material may be deposited to different thicknesses to rectify a non-planarity in the heat pipe surface(s), or to induce a non-planarity in the base plate surface to accommodate IC die of different thicknesses.

In advantageous embodiments, the base plate material is formed with high-throughput additive manufacturing (HTAM) process, such as, but not limited to spray deposition techniques. An HTAM process entails the dispense of one or more source powders upon a workpiece surface where the powder(s) coalesce into the base plate material. With such deposition techniques, the base plate material deposited at block 220 may be rapidly formed selectively upon any portion of a heat pipe surface in an additive manner, and at high rates (e.g., 50 μm/sec, or more). As described further below, one or more spray nozzles may be scanned over the heat pipe surface (or any portion thereof), for example depositing a base plate material having high thermal conductivity along a path that substantially covers what will become the hot interface of the heat pipe with the IC die or package.

The base plate material deposited at block 220 may have strong adhesion to the underlying heat pipe surface(s). The base plate material may have a composition, and/or microstructure, and/or surface characteristic distinct from that of the underlying heat pipe(s), and which advantageously has a high thermal conductivity in one or more dimensions. For example, the base plate material may have a composition that has high thermal conductivity in an x-y plane over one side of the heat pipe(s) and/or high thermal conductivity in a z-dimension through a thickness of the base plate material over the heat pipe(s). By using HTAM processes to deposit the base plate material, a base plate that is contiguous with the heat pipe(s) may be fabricated as a portion of the thermal solution suitable for a wide range of IC die package applications having a variety of different constraints on the package thickness and lateral dimensions.

Methods 201 continue at block 225 where the base plate material may be planarized. Block 225 is optional depending on the planarity and/or level of surface roughness achieved through the additive process(es) practiced at block 220. In some embodiments, where the base plate material deposited at block 220 has an RMS surface roughness exceeding 10 μm, a polish or lapping process may be performed at block 225 to reduce the RMS surface roughness of the base plate material to no more than 1 μm.

Methods 201 complete at output 230 where the heat pipe with contiguous base plate material, is provided as a thermal solution (e.g., offered to a system supplier in microelectronics assembly supply chain) for use in the further assembly of a microelectronic device or system.

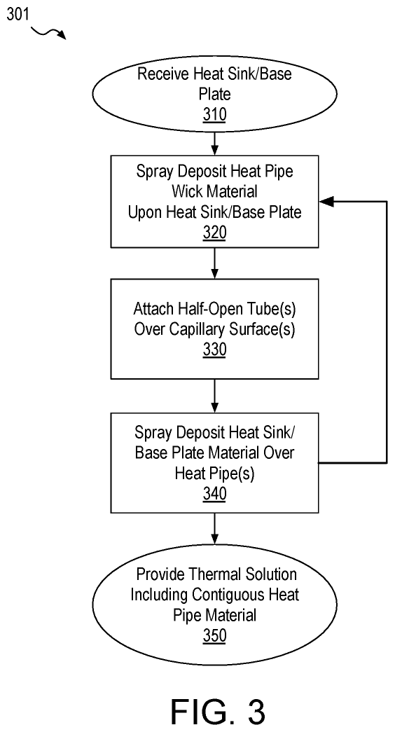

FIG. 3 is a flow diagram of methods 301 for forming a heat exchanger with contiguous heat pipe wick material suitable for integration into an IC die thermal solution, in accordance with some embodiments. Methods 301 begin with receiving a heat sink or a base plate at block 310. For embodiments where the starting material is a heat sink, a cold interface of a heat pipe is formed directly on the heat sink material. For embodiments where the starting material is a base plate, a hot interface of a heat pipe is formed directly on the base plate material.

At block 320, heat pipe material is deposited over the working surface of the heat sink or base plate that is to become the cold/hot interface of a system-level IC die thermal solution. In exemplary embodiments, the heat pipe material deposited at block 320 is wick material that is to provide the capillary action of the heat pipe. The heat pipe wick material may be deposited on some predetermined portion (i.e., length) of the heat sink (or base plate), or over an entirety of the heat sink (or base plate). For example, a substantially uniform thickness of wick material may be deposited upon an entirety of a surface of the heat sink or base plate. Alternatively, a thickness of wick material may be deposited upon only a portion of a surface of the heat sink or base plate to which a heat pipe is to be confined. For example, a path over which a heat pipe is to contact the heat sink/base plate material may be additively defined by selectively depositing the wick material only along the path so that a remainder of the working surface has no wick material.

In advantageous embodiments, the wick material is deposited with an HTAM technique in which one or more source powders are dispensed upon a workpiece surface where the powder(s) coalesce into the wick material. With such deposition techniques, the wick material deposited at block 320 may be rapidly formed selectively upon any portion of a working surface in an additive manner, and at high rates. One or more spray nozzles may be scanned over the working surface (or any portion thereof), for example depositing a wick material having high thermal conductivity and suitable capillary properties along a path that substantially covers what will function as either a cold interface or a hot interface of the heat pipe.

The wick material deposited at block 320 may have strong adhesion to the underlying working surface. The wick material may have a composition, and/or microstructure, and/or surface characteristic distinct from that of the underlying heat sink material or base plate material. The wick material advantageously has a high thermal conductivity in one or more dimensions. For example, the wick material may have a composition that has a thermal conductivity exceeding 100 Wm⁻¹K⁻¹. The wick material may also have non-zero porosity and/or significant surface roughness, which promote capillary action needed for wick material. By using HTAM processes to deposit the wick material, heat pipes that are contiguous with the heat sink or base plate may be fabricated as a portion of the thermal solution suitable for a wide range of IC die package applications having a variety of different constraints on the package thickness and lateral dimensions.

Methods 301 continue at block 330 where one or more half-open tubes or pipes are attached to enclose the wick material deposited at block 320. In contrast to a complete heat pipe, a half-open tube has an opening over a longitudinal length that is to be bonded with the working surface and/or wick material. For example, where only a partial length of a heat pipe is to be attached to a heat sink or base plate surface, only that partial length may be half-open. Where an entire length of a heat pipe is to be attached to the heat sink or base plate surface, that entire length comprises a half-open tube. The half-open tube may be attached to the working surface and/or wick material with any suitable joinery filler as such intervening material should not pose a significant thermal bottleneck when in parallel with the contiguous wick material that was deposited at block 320. For embodiments where the wick material is contiguous with a heat sink, heat transfer from the wick material at the cold interface of the heat pipe may be unimpeded by any intervening joinery filler (e.g., solder). For embodiments where the wick material is contiguous with a base plate, heat transfer into the wick material at the hot interface of the heat pipe may be unimpeded by any intervening joinery filler (e.g., solder).

Methods 301 may continue at block 340 where supplemental heat sink/base plate material is deposited over the heat pipes formed at block 330. Block 340 is optional and may be performed, for example, in preparation for practicing one or more additional iterations through blocks 320 and 330 to form another level of heat pipe(s). The material deposited at block 340 may be the same or different than the material deposited at block 320. In some embodiments, the same HTAM technique practiced at block 320 is employed to deposit supplemental material at block 340. In some embodiments, heat pipes formed thus far are embedded and/or planarized over in preparation for the further deposition of additional wick material (e.g., during a second iteration of block 320). At block 340, thermally conductive material may be deposited over some predetermined portion of the base plate, for example to backfill between adjacent heat pipes.

Methods 301 may then continue with another iteration of blocks 320-340, or not, prior to output 350 where a heat exchanger with a contiguous heat pipe material is provided as a thermal solution (e.g., offered to a system supplier in microelectronics assembly supply chain) for use in the further assembly of a microelectronic device or system.

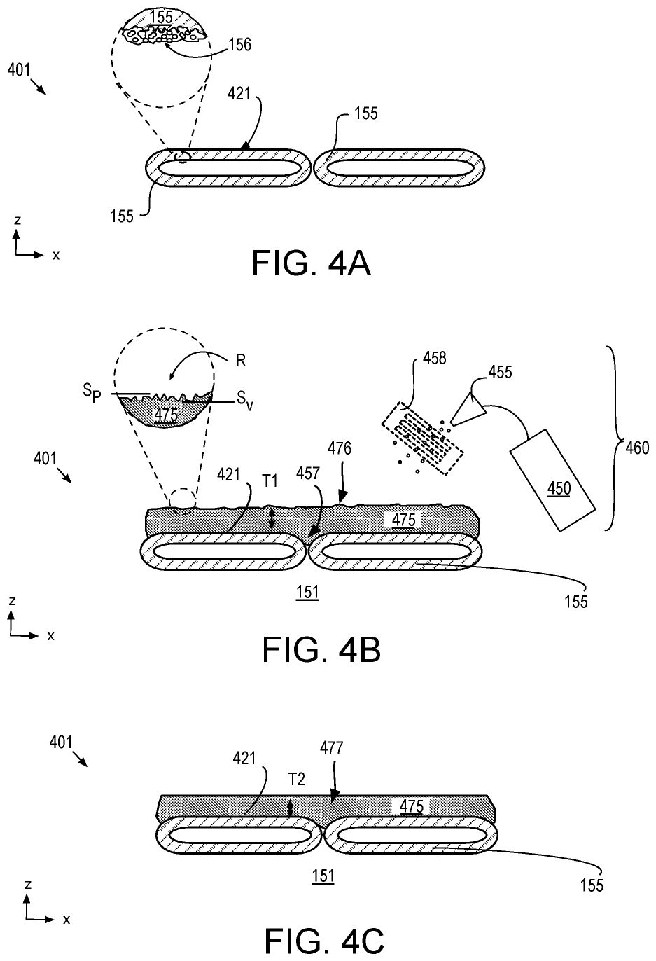

FIG. 4A-4C illustrate cross-sectional views of a system-level IC die heat exchanger structure 401 evolving as the methods 201 are practiced, in accordance with some specific embodiments. The sectional view depicted in FIG. 4A-4C is along the sectional plane introduced in FIG. 1A.

Referring first to FIG. 4A, IC die heat exchanger structure 401 includes a heat pipe 155, which may be free-standing as illustrated, or coupled with a heat sink (not depicted). In some embodiments, a cold interface of heat pipe 155 is press fit into and/or soldered to a cavity within heat sink while the hot interface is free-standing, as illustrated in FIG. 4A.

Heat pipe 155 is a closed container that utilizes evaporative cooling to move heat from a heat source (e.g., from a hot interface proximal to a hot IC die) to a heat sink (not depicted). Heat pipe 155 operates on phase transition principle. For example, heat pipe 155 includes a porous wick material 156 on an interior surface of at least the hot interface, and an internal open space or passage over wick material 156 where vapor may be conveyed. In the illustrated example, wick material 156 is a coating, contiguous with, a structural conduit material of heat pipe 155. Heat pipe 155 contains a coolant fluid (not depicted), which may be in liquid phase and/or vapor phase as a function of temperature at any location within heat pipe 155.

The liquid phase of the coolant fluid in contact with wick material 156 at the hot interface may evaporate, thereby absorbing heat from the hot interface. The resulting vapor phase of the coolant fluid may be conveyed within the open passage until condensing at a cold interface with heat sink, thereby releasing latent heat to the heat sink. The liquid phase of the coolant fluid is then conveyed back to the hot interface through wick material 156, for example, by capillary action. Thus, in heat pipe 155, the change of phase of the coolant fluid between liquid and vapor aids in the transfer of heat to a remote heat sink, thereby cooling an IC die through the hot interface.

In the example shown in FIG. 4B, an HTAM process 460 is performed to form base plate material 475. HTAM process 460 propels one or more source materials 450, in the form of a dry powder, through a dispense jet, or nozzle, 455. HTAM process 460 may be controlled to deposit base plate material 475 over a portion of heat pipe 155. During the deposition process, dispense nozzle 455 may be displaced relative to heat pipe 155 along a predetermined deposition path to cover some portion, or all, of heat pipe 155. Heat spreader material need not be deposited on any regions of heat exchanger structure 401 not compatible with the HTAM process. For example, the HTAM process may be confined to within a footprint of heat pipe 155 that is to overlap an IC die package.

Base plate material 475 is formed from jet-borne particles that have impacted together to build up a solid upon heat pipe hot interface 421. Base plate material 475 is therefore in direct contact with, or contiguous with, heat pipe 155. During HTAM process 460, the jet gas may be heated, for example to temperatures below the melting temperature of the particles. However, for cold spray examples there may be no separate external heating of source material 450 and/or heat exchanger structure 401. Instead, energy is applied through particle momentum transfer. Source materials 450 may comprise a single material or blends of two or more materials. Malleable and/or ductile particles, such as metallic powders, may be entrained in a high-velocity gas jet and bond to each other and/or the underlying substrate (e.g. heat pipe hot interface 421) upon impact. As described in greater detail below, malleable particles may deform upon impact into flattened particles ranging in size from 5 microns to 200 microns that may build upon each other.

As further illustrated in FIG. 4B, HTAM process 460 may optionally include the use of a deposition stencil 458 to confine the deposition of base plate material 475 to feature dimensions smaller than a width of the spray nozzle orifice. Deposition stencil 458 is illustrated in dashed line to emphasize its use is optional, for example where base plate material 475 is to be deposited with a transverse feature width of 100 μm, or less.

Base plate material 475 may be deposited to any thickness T1, as measured in a direction substantially orthogonal to a plane of the hot interface of heat pipe 155. In the illustrated example, thickness T1 varies over the area of base plate material 475 in a manner that at least partially backfills a gap 457 between two adjacent lengths of heat pipe 155 and/or overcomes any non-planarity associated with hot interface 421. In advantageous embodiments, thickness T1 is at least 100 μm to impart significant structural rigidity to heat exchanger structure 401. In some exemplary embodiments, thickness T1 is 100-2000 μm.

As further illustrated in the expanded view of FIG. 4B, base plate material 475 may have a surface roughness R significantly larger than that of the underlying heat pipe hot interface 421. Interface 421 may be specular, for example, while base plate material 475 has an as-deposited surface 476 that is non-specular. Heat pipe interface 421 may have an RMS surface roughness of 1-10 μm, for example while as-deposited surface 476 may have an RMS roughness exceeding 10 μm. For the cross-section illustrated in FIG. 4B, surface roughness R may also be characterized as a roughness profile with peaks and valleys varying between a minimum surface profile valley Sᵥ and a maximum surface profile peak Sₚ that differ by at least 10 μm in the vertical direction (e.g., z-dimension).

FIG. 4C illustrates an example where base plate material 475 is planarized by lapping and/or polishing the as-deposited base plate surface 476 into a polished base plate surface 477. In addition to smoothening the base plate surface, such processing may improve planarity of the base plate material 475 to match a planar IC die surface. In some embodiments, following the polish, base plate surface 476 may have an RMS surface roughness less than 10 μm, and a thickness T2 that may range from 100-1000 μm.

The composition and/or microstructure and/or surface morphology of base plate material 475 may be selected to achieve a high thermal conductivity and/or high bulk modulus. In some embodiments, base plate material 475 has an effective thermal conductivity coefficient over 200 Wm⁻¹K⁻¹ (e.g., in the range of 200-1000 Wm⁻¹K⁻¹) within the X-Y plane parallel and/or within a Z plane. Base plate material 475 may also have a relatively high bulk modulus, which may advantageously provide mechanical stiffening to heat exchanger structure 401 and/or provide physical protection to the underlying heat pipe 155. In some examples, base plate material 475 has a bulk modulus over 10 GPa and/or a hardness over 100 on the Shore A scale. Base plate material 475 may have a substantially homogenous composition, for example where HTAM process 460 employs only one source material 450. Alternatively, base plate material 475 may be a composite of a plurality of material particles having different compositions, for example where HTAM process 460 employs multiple source materials 450. Base plate material 475 may also have a layered structure where different source materials 450 are switched during a multi-phase, sequential HTAM deposition process.

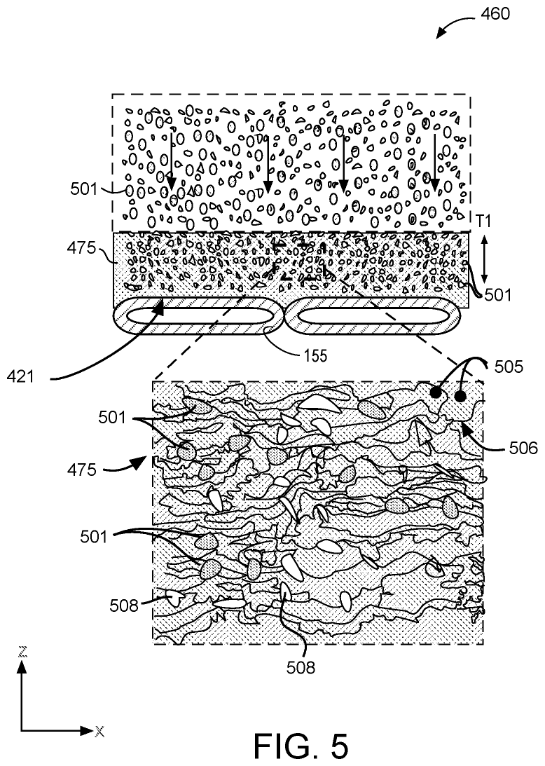

FIG. 5 further illustrates deposition of particles 501 to form base plate material 475 upon heat pipe hot interface 421, in accordance with some embodiments of HTAM process 460. As shown, the microstructure of base plate material 475 comprises embedded particles 501 and voids 508. At sufficient magnification, boundaries between particles 501 are apparent as distinguished from atomic deposition processes, such as plating. Lamellar structures may be evident within base plate material 475, which are indicative of impact between particles and a substrate surface, where most of the particles plastically deform and flatten or otherwise splat. Particles may impact each other in succession, forming stacks of contiguous irregular or regular-shaped lamellae 505. In some embodiments, individual lamellae 505 are delineated by discernable boundaries 506, which may be observed at magnifications below 500×. In other embodiments, lamellae 505 may not be apparent at even higher magnifications.

Because particles 501 may have irregular shapes, voids 508 can appear at boundaries 506 between embedded particles 501. As such, the porosity of base plate material 475 may be higher than heat pipe (material) 155. Porosity may be expressed as % voiding area (as measured from a cross sectional micrograph within the x-y plane illustrated in FIG. 5). The microstructure of materials formed by cold spray, thermal spray, or a similar HTAM process, may therefore have larger void areas than materials having substantially the same composition formed by other techniques. Voiding area is a quality parameter that can be monitored and controlled in spray deposition processes. While bulk material, and thin film materials deposited by other means (e.g., atomic techniques) typically have void areas of zero, materials deposited by HTAM processes (e.g., cold spray) may have void areas ranging from 0.1% to 0.5%, or more. Hence, the presence of voids 508, is indicative of base plate material 475 having been formed by an HTAM process, such as spray deposition (e.g., a cold spray process).

In some exemplary embodiments, particles 501 comprise a metal, such as one or more of, indium, bismuth, tin, gallium, copper, iron, nickel, manganese, molybdenum, chromium, silver, gold, titanium, aluminum, tungsten, or platinum. Particles 501 of metals may be crystalline, with crystal orientations of particles 501 being random so that base plate material 475 lacks significant crystal texture. In some other exemplary embodiments, particles 501 comprise a non-metal, such as one or more of, silicon, carbon, nitrogen or oxygen. Such non-metal particles may also be crystalline, for example with crystalline carbon present as diamond particles, or graphite particles. In some embodiments, particles 501 are compounds, such as AlN particles, BN particles, SiC particles, Al₂O₃ particles, etc.

In still other embodiments, metal particles (e.g., one or more of In, Bi, Sn, Ga, Cu, Fe, Ni, Mn, Mo, Cr, Ag, Au, T1, Al, W, or Pt) may be intermixed with non-metal particles (e.g., one or more of C, Si, O, or N). Base plate material 475 may therefore comprise a blend of metal and non-metal materials. Particles of the non-metal, (e.g., diamond or graphite, metal nitrides, metal oxides etc.) may be embedded in a matrix of the malleable and/or ductile metal particles. Particles 501 may also have a composition that varies as a function of thickness T1. For example, in either layered or gradient structures, particles 501 proximal to hot interface 421 may have a first composition while particles 501 distal from IC hot interface 421 may have a second composition.

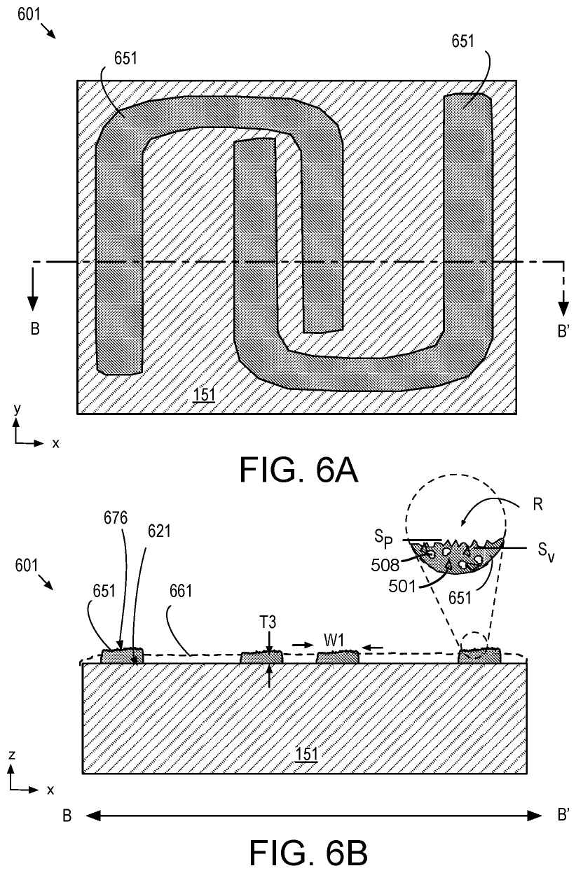

FIG. 6A-10A illustrate a plan view of an IC die heat exchanger structure 601 evolving as methods 301 (FIG. 3) are practiced, in accordance with some embodiments. FIG. 6B-10B illustrate a cross-sectional view of IC die heat exchanger structure 601 corresponding to FIG. 6A-10A, respectively.

As shown in FIGS. 6A and 6B, wick material 651 has been deposited onto a cold interface 621 of heat sink 151. In exemplary embodiments, heat sink 151 comprises a fin array, for example as illustrated in FIG. 1B. In some HTAM embodiments, a spray jet is scanned along a path that the heat pipe is to follow on heat sink 151. The HTAM spray nozzle may be scanned at a predetermined rate to selectively deposit wick material 651 to any desired thicknesses T3. In some embodiments, wick material thickness T3 is at least 10 μm and may be 100 μm, or more. Alternatively, wick material 651 may be spray deposited over an entirety of heat sink 151, as denoted by dashed line 661.

Wick material 651 may be deposited with HTAM process 460, substantially as described above. For example, one or more source materials in the form of a dry powder may be propelled through a dispense jet, or nozzle to form wick material 651 over at least a portion of heat sink 151. Wick material 651 formed from jet-borne particles that have impacted together to build up upon heat sink 151. Wick material 651 is therefore in direct contact with, or contiguous with, heat sink 151. The jet gas may be heated, or there may be no separate external heating of source material and/or heat exchanger structure 601. Source materials may comprise a single material or blends of two or more materials. Malleable and/or ductile particles, such as metallic powders, may be entrained in a high-velocity gas jet and bond to each other and/or the underlying substrate (e.g. heat sink cold interface 621) upon impact. In the same manner as described above for base plate material, malleable particles propelled upon heat sink 151 may deform upon impact into flattened particles ranging in size from 5 microns to 200 microns that may build upon each other.

HTAM deposition may optionally include the use of a deposition stencil to confine the deposition of wick material 651 to feature dimensions smaller than a width of the spray nozzle orifice. A deposition stencil may be used, for example, where wick material 651 is to be deposited with a transverse feature width W1 of 100 μm, or less.

As further illustrated in the expanded view of FIG. 6B, wick material 651 may have a surface roughness R significantly larger than that of the underlying heat sink cold interface 621. Interface 621 may be specular, for example, while wick material 651 has an as-deposited surface 676 that is non-specular. Heat sink interface 621 may have an RMS surface roughness of 1-10 μm, for example while wick material surface 676 may have an RMS roughness of at least 10 μm. For the cross-section illustrated in FIG. 6B, surface roughness R may also be characterized as a roughness profile with peaks and valleys varying between a minimum surface profile valley Sᵥ and a maximum surface profile peak Sₚ that differ by at least 10 μm in the vertical direction (e.g., z-dimension).

The composition and/or microstructure and/or surface morphology of wick material 651 may be selected to achieve high thermal conductivity and/or high capillary action. In some embodiments, wick material 651 has an effective thermal conductivity coefficient over 200 Wm⁻¹K⁻¹, and may be in the range of 200-1000 Wm⁻¹K⁻¹. Wick material 651 may also have a relatively high porosity, which may provide the capillary action advantageous for the interior of a heat pipe. As noted above, voids 508 can appear at boundaries between embedded particles. The larger void areas of materials formed by cold spray, thermal spray, or a similar HTAM process, may therefore be leveraged for good wicking properties. The porosity of wick material 651 may be significantly higher than heat sink (material) 151, which may have a void area of zero. In some embodiments wick material 651 has a void area of between 0.1% and 0.5%, or more as-deposited. In some embodiments, the effective void area of the layer comprising wick material 651 may be increased to 10% or higher by using a source material having small powder particle size (e.g. <20 um) and spraying it through a stencil (e.g., a mesh) with very small feature dimensions (e.g. <50 um).

The particle deposition mechanism illustrated in FIG. 5 in the context of the formation of base plate material 475 is also applicable to the formation of wick material 651. For example, the microstructure of wick material 651 will also comprise embedded particles 501 and voids 508 (as depicted in FIGS. 5 and 6B). At sufficient magnification, boundaries between particles are apparent as distinguished from atomic deposition processes, such as plating. Lamellar structures may also be evident within wick material 651 at magnifications below 500×.

Wick material 651 may have a substantially homogenous composition. Alternatively, wick material 651 may be a composite of a plurality of material particles having different compositions, for example where an HTAM deposition propels multiple source materials. Wick material 651 may also have a layered structure where source materials are switched during a multi-phase, sequential HTAM deposition process. In some exemplary embodiments, particles 501 comprise a metal, such as one or more of, indium, bismuth, tin, gallium, copper, iron, nickel, manganese, molybdenum, chromium, silver, gold, titanium, aluminum, tungsten, or platinum. Particles 501 of metals may be crystalline, with crystal orientations of particles 501 being random so that wick material 651 lacks significant crystal texture. In some other exemplary embodiments, particles 501 comprise a non-metal, such as one or more of, silicon, carbon, nitrogen or oxygen. Such non-metal particles may also be crystalline, for example with crystalline carbon present as diamond particles, or graphite particles. In some embodiments, particles 501 are compounds, such as AN particles, BN particles, SiC particles, Al₂O₃ particles, etc.

In still other embodiments, metal particles (e.g., one or more of In, Bi, Sn, Ga, Cu, Fe, Ni, Mn, Mo, Cr, Ag, Au, T1, Al, W, or Pt) may be intermixed with non-metal particles (e.g., one or more of C, Si, O, or N). Wick material 651 may therefore comprise a blend of metal and non-metal materials. Particles of the non-metal, (e.g., diamond or graphite, metal nitrides, metal oxides etc.) may be embedded in a matrix of the malleable and/or ductile metal particles. Particles 501 may also have a composition that varies as a function of thickness T3. For example, in either layered or gradient structures, particles 501 proximal to cold interface 621 may have a first composition while particles 501 distal from cold interface 621 may have a second composition.

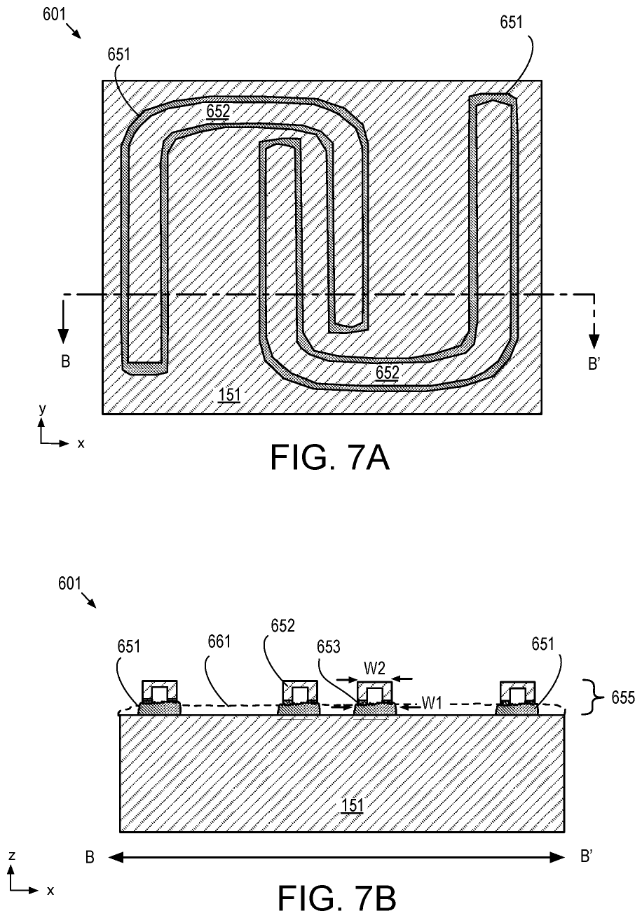

FIG. 7A-7B further illustrate heat exchanger structure 601 following attachment of half-round tubes 652. The half-round profile depicted in FIG. 7B is one example, and the half-round profile may vary from curved to rectilinear. In this example, half-round tubes 652 are three-sided channels or conduits with bends along their lengths, which follow predetermined paths substantially matching the wick material 651. As further illustrated, half-round tubes 652 have a transverse width W2 that is smaller than wick material width W1 so that half-round tubes 652 are joined to wick material 651 by solder/braze filler 653. Alternatively, where half-round tubes 652 have a transverse width W2 that is larger than wick material width W1, half-round tubes 652 may be joined by solder/braze filler to heat sink 151. Half-round tubes 652 enclose wick material 651, forming heat pipe(s) 655. Although not illustrated, any suitable fluid may be dispensed within heat pipe 655 just prior to it becoming a sealed vessel.

In some embodiments, half-round tubes 652 have a different composition or microstructure than wick material 651. Half-round tubes 652 may also have wick material. Such wick material may take any form, but in some embodiments where another HTAM process is employed to deposit wick material within an interior of half-round tubes 652, wick material on the various interior surfaces of heat pipes 655 may be substantially the same. In other embodiments where half-round tubes 652 have wick material formed by other than HTAM processes, wick material on an interior of half-round tubes 652 may differ from wick material 651.

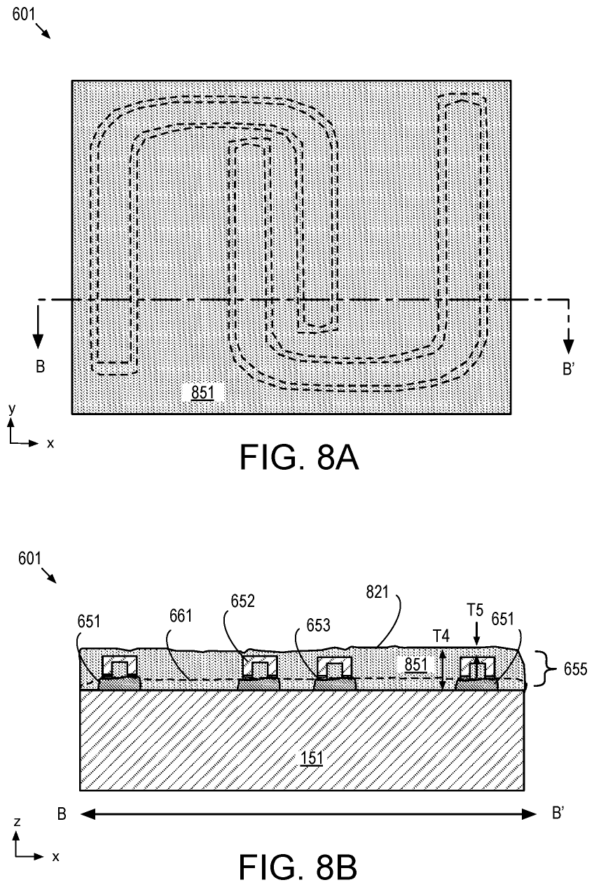

FIG. 8A-8B further illustrate heat exchanger structure 601 following deposition of a supplemental heat sink/base plate material 851. Supplemental heat sink/base plate material 851 may be any material having a high thermal conductivity (e.g., 100-1000 Wm⁻¹K⁻¹), and in exemplary embodiments is deposited with an HTAM process (e.g., HTAM process 460). Supplemental heat sink/base plate material 851 is therefore also contiguous with heat sink 151. In some embodiments, supplemental heat sink/base plate material 851 has a different composition and/or microstructure than heat sink 151. Supplemental heat sink/base plate material 851 may have any of the compositions and/or properties described above for either base plate material 475 or wick material 651, for example.

In the example illustrated in FIG. 8A-8B, heat pipes 655 are completely embedded within supplemental heat sink/base plate material 851. Following an HTAM process where supplemental heat sink/base plate material 851 is deposited to a greater thickness T4 over heat sink 151 and a lesser thickness T5 over heat pipes 655, supplemental material surface 821 may be substantially planar. In some examples, thickness T4 is 1-4 mm while thickness T5 is 100-1000 μm. Optionally, supplemental material surface 821 may be subtractively planarized as well, for example with any polishing process.

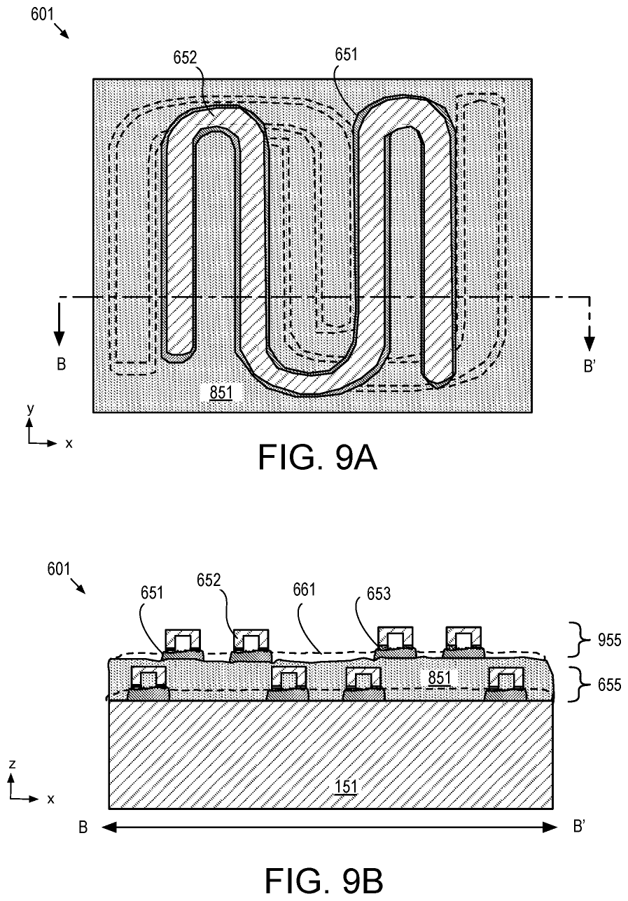

FIG. 9A-9B illustrate some embodiments where heat exchanger structure 601 has been further processed to include a plurality of heat pipe levels. Heat exchanger structure 601 includes heat pipes 955 over heat pipes 655. In the illustrated embodiment, heat pipes 955 include wick material 651 that is contiguous with supplemental heat sink/base plate material 851. Heat pipes 955 further include half-round tubes 652 bonded to wick material 651 through solder/braze filler 653 in substantially the same manner as described above for heat pipes 655. Hence, heat pipes 955 may be formed by performing a second iteration of the processes performed to form heat pipes 655.

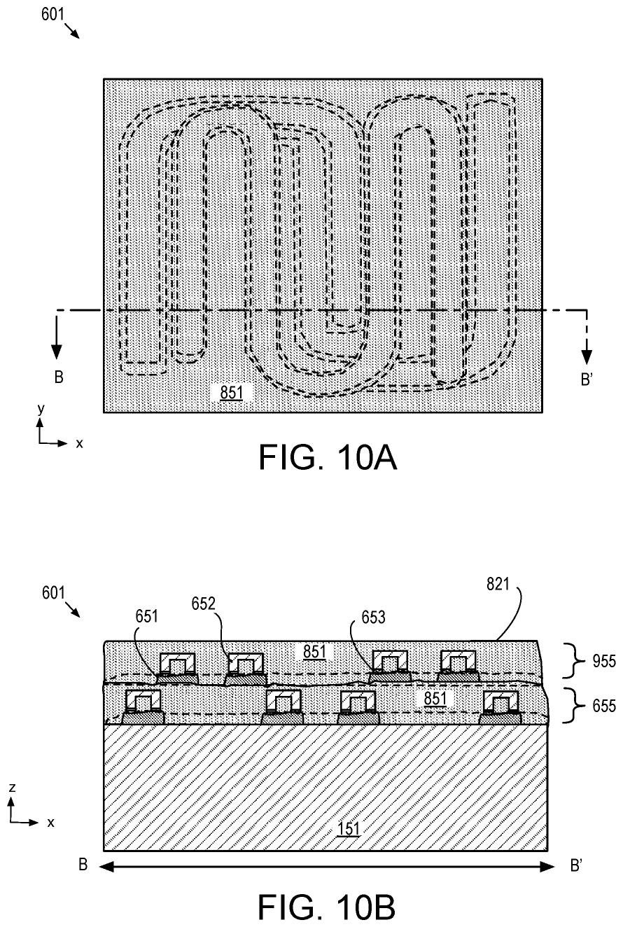

FIG. 10A-10B illustrate some embodiments where heat exchanger structure 601 has been further processed to embed heat pipes 955 within supplemental heat sink/base plate material 851, substantially as described above. Although two heat pipe levels are illustrated in FIG. 10A-10B, any number of heat pipes levels may be similarly embedded within heat sink material as facilitated by the HTAM techniques described herein. In this example, supplemental heat sink material surface 821 has been polished to be substantially planar and/or specular.

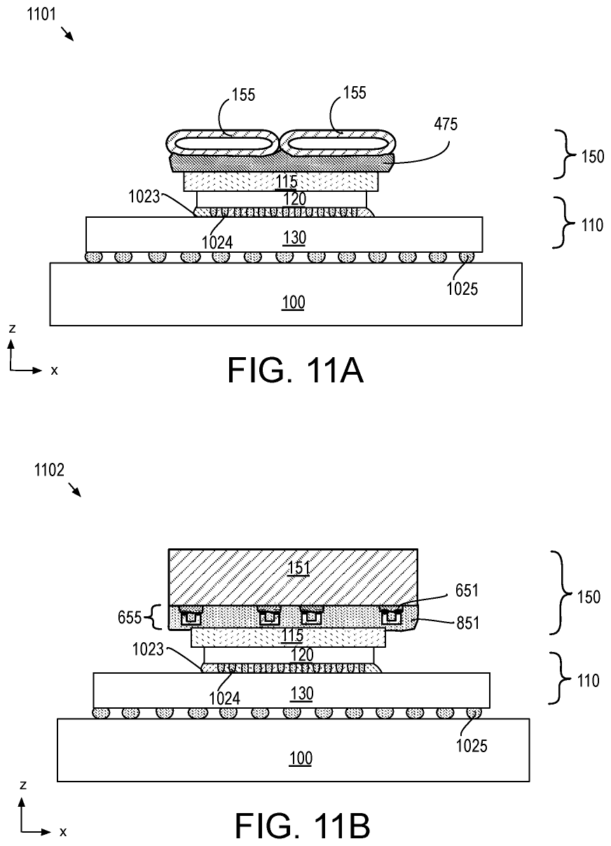

FIG. 11A illustrates a cross-sectional view of a system-level IC die assembly 1101, in accordance with some mobile device embodiments. IC die assembly 1101 includes an IC die package 110 interconnected to a system PCB 100 through second-level interconnects (SLI) 1025. PCB 100 may include epoxy resins, for example, and/or polytetrafluoroethylene (Teflon), cotton-paper reinforced epoxy (CEM-3), phenolic-glass (G3), paper-phenolic, polyester-glass, or any combination thereof. SLI 1025 may be solder features, such as an array of solder balls or solder bumps, etc. IC die package 110 includes package substrate 130 interconnected to IC die 120 through first-level interconnects (FLI) 1024. FLI 1024 are embedded within an underfill 1023, and may be any type of interconnect features known to be suitable for electrically coupling an IC die, such as solder bumps, microbumps, pillars, etc.

Package substrate 130 may include any suitable type of substrate capable of providing electrical communication between an IC die 120 and PCB 100. In some examples, package substrate 130 includes one or more of crystalline semiconductor (e.g., silicon), epoxy resins, polytetrafluoroethylene (Teflon), cotton-paper reinforced epoxy, phenolic-glass, paper-phenolic, polyester-glass, ABF (Ajinomoto Build-up Film), or any combination thereof. In some embodiments, substrate 130 comprises alternating layers of a dielectric material and metal built-up around a core layer (either a dielectric core or a metal core). In other embodiments, substrate 130 is a coreless multi-layer substrate. Other types of substrates and substrate materials may also be used (e.g., ceramics, sapphire, glass, etc.). In alternative embodiments, substrate 130 may comprise alternating layers of dielectric material and metal that were built-up over IC die 120, sometimes referred to as a “bumpless build-up process.” Where such an approach is utilized, FLI 1024 may not be needed (as the build-up layers may be in direct contact with IC 120).

IC die 120 may have any type of circuitry with any function, such as, but not limited to, power management ICs (PMICs), radio frequency communication ICs (RFICs), microprocessors (e.g., application processors, central processors, graphics processors), memory ICs (e.g., DRAM), or System on a Chip (SoC) ICs that may include two or more of these types of ICs, etc. Any of these types of IC die may have any footprint area, for example from a few mm², to around 1000 mm², or more. Any of these types of IC die may have any thickness, for example from a few tens of microns (μm) to 800 μm, or more. Although only one IC die 120 is illustrated, package substrate 130 may host more than one IC die 120 in any multi-chip package (MCP) configuration.

System-level thermal solution 150 may be coupled to IC die package 110 through any TIM 115. TIM 115 may be any thermal grease or pad preform known to be suitable for the application, such as graphitic polymer composites (e.g., crystalline graphite, pyrolytic graphite and silicone-based polymers or synthetic rubbers), or metallic alloys (e.g., comprising two or more of In, Au, Sn, Ag, Bi, Ga, or Cu). For system-level IC die assembly 1101, thermal solution 150 is a heat exchanger that includes base plate 475 in direct contact with TIM 115 and in direct contact (i.e., contiguous with) heat pipe 155. Base plate 475 may have any of the attributes described above.

FIG. 11B illustrates a cross-sectional view of a system-level IC die assembly 1102, in accordance with some desktop or server computer platform embodiments. IC die assembly 1102 similarly includes IC die package 110 interconnected to a system PCB 100 through second-level interconnects (SLI) 1025. In this example, thermal solution 150 is a heat exchanger that includes heat pipes 655 are contiguous with heat sink 151, and more specifically, wick material 651 is in direct contact with heat sink 151. Heat pipes 655 are coupled to TIM 115 through supplemental heat sink/base plate material 851, but in other embodiments heat pipes 655 may be in direct contact with TIM 115.

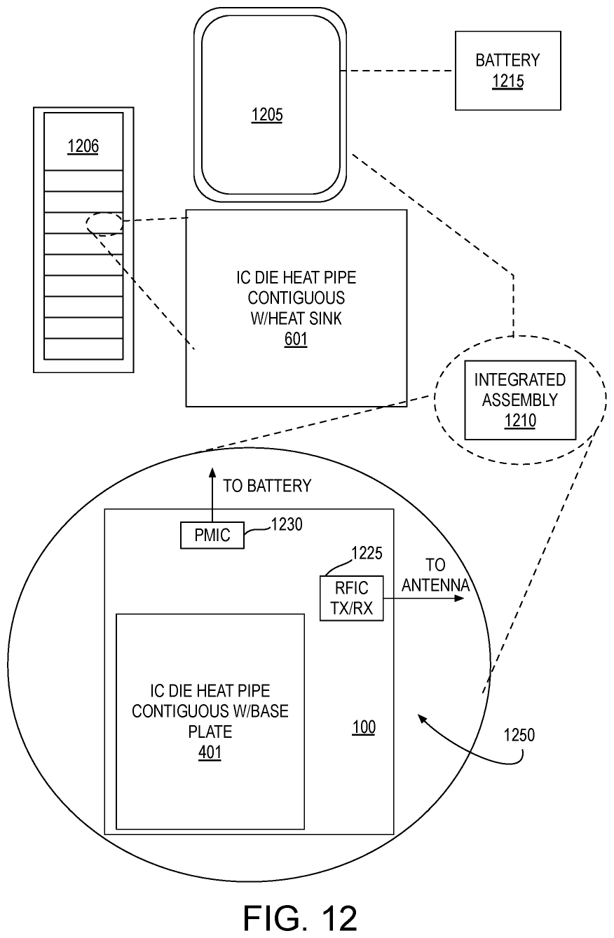

In some embodiments, a computer platform includes an IC die thermal solution with a contiguously integrated heat pipe, for example having one or more of the attributes described above. FIG. 12 illustrates a mobile computing platform and a data server computing platform, each employing an IC die thermal solution with a contiguously integrated heat pipe. The server platform 1206 may be any commercial server, for example including any number of high-performance computing platforms disposed within a rack and networked together for electronic data processing. In the exemplary embodiment, server platform 1206 includes system-level IC die heat exchanger structure 601, for example as described above.

The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), a chip-level or package-level integrated assembly 1210, and a battery 1215. Integrated assembly 1210 may include a memory IC and processor IC, and may further include system-level IC die heat exchanger structure 401, for example as described elsewhere herein. In the example shown in the expanded view 1250, IC die heat exchanger structure 401 is coupled to PCB 100 that may further host one or more additional IC die packages, such as PMIC 1230 and RFIC 1225, for example. PMIC 1230 may perform battery power regulation, DC-to-DC conversion, etc., and so has an input coupled to battery 1215 and with an output providing a current supply to other functional modules. RFIC 1225 may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 4G, 5G, and beyond.

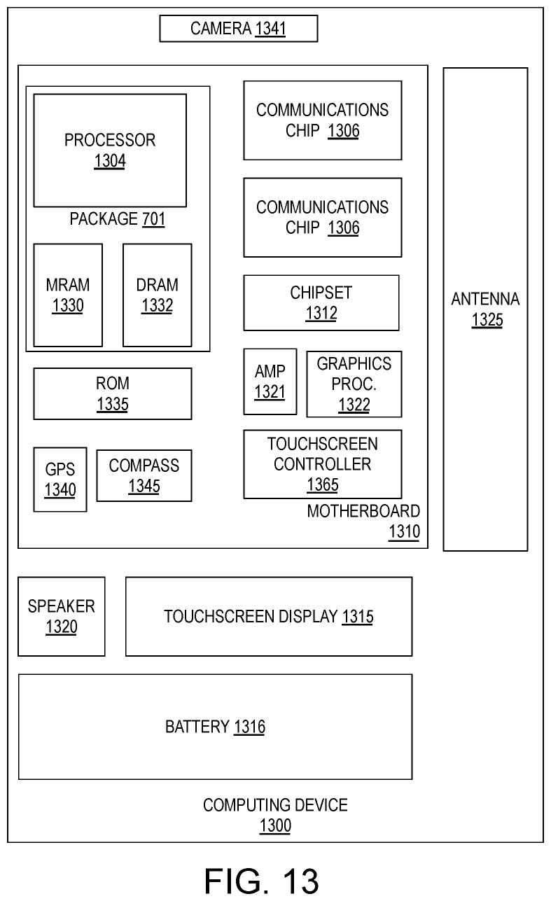

FIG. 13 is a functional block diagram of an electronic computing device 1300, in accordance with an embodiment of the present invention. Computing device 1300 may be found inside mobile platform 1205 or server platform 1206, for example. Device 1300 further includes a motherboard 1310 hosting a number of components, such as, but not limited to, a processor 1304 (e.g., an applications processor). Processor 1304 may be physically and/or electrically coupled to motherboard 1310. In some examples, processor 1304 is coupled to IC die heat exchanger structure with a contiguously integrated heat pipe, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1306 may also be physically and/or electrically coupled to the motherboard 1310. In further implementations, communication chips 1306 may be part of processor 1304. Depending on its applications, computing device 1300 may include other components that may or may not be physically and electrically coupled to motherboard 1310. These other components include, but are not limited to, volatile memory (e.g., DRAM 1332), non-volatile memory (e.g., ROM 1335), flash memory (e.g., NAND or NOR), magnetic memory (MRAM 1330), a graphics processor 1322, a digital signal processor, a crypto processor, a chipset 1312, an antenna 1325, touchscreen display 1315, touchscreen controller 1365, battery 1316, audio codec, video codec, power amplifier 1321, global positioning system (GPS) device 1340, compass 1345, accelerometer, gyroscope, speaker 1320, camera 1341, and mass storage device (such as hard disk drive, solid-state drive (SSD), compact disk (CD), digital versatile disk (DVD), and so forth), or the like. In some exemplary embodiments, at least one of the functional blocks noted above are coupled to IC die heat exchanger structure that includes a contiguously integrated heat pipe, for example as described elsewhere herein.

Communication chips 1306 may enable wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1306 may implement any of a number of wireless standards or protocols, including but not limited to those described elsewhere herein. A first communication chip 1306 may be dedicated to shorter-range wireless communications, such as Wi-Fi and Bluetooth, and a second communication chip 1306 may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

In first examples, an integrated circuit (IC) die package heat exchanger comprises a heat pipe to contain flows of a vapor and a liquid between a hot interface and a cold interface. The a base plate is contiguous with the hot interface of the heat pipe, the base plate has a substantially planar surface to interface with a surface of an IC die package, and the base plate has a different composition or microstructure than the heat pipe.

In second examples, for any of the first examples the base plate has a thickness of at least 100 μm.

In third examples, in any of the first through second examples the base plate has a thermal conductivity of at least 100 Wm⁻¹K⁻¹.

In fourth examples, for any of the first through third examples the base plate comprises at least one of a metal, silicon, or carbon.

In fifth examples, for any of the first through fourth examples the base plate has a void area of at least 0.1%.

In sixth examples, for any of the first through fifth examples the base plate has an RMS surface roughness below 10 μm.

In seventh examples, for any of the first through sixth examples the heat exchanger comprises a wick material that is in direct contact with the base plate.

In eighth examples, for any of the seventh examples the wick material has a thickness of at least 10 μm.

In ninth examples, an integrated circuit (IC) die package heat exchanger comprises a heat pipe to contain flows of a vapor and a liquid between a hot interface and a cold interface, the heat pipe comprising a wick material. The heat exchanger further comprises a heat sink contiguous with the wick material at the cold interface of the heat pipe. The wick material has a different composition or microstructure than the heat sink.

In tenth examples, for any of the ninth examples the wick material has a thickness of at least 10 μm and a void area of at least 0.1%.

In eleventh examples, for any of the ninth through tenth examples the heat pipe comprises a half-open tube bonded to the wick material by an intervening filler material, the wick material having a different composition or microstructure than the half-open tube or filler material.

In twelfth examples, a computer platform comprises an IC die, the IC die package heat exchanger of any of the first through eighth examples, and a thermal interface material (TIM) between the IC die and the base plate.

In thirteenth examples, for any of the twelfth examples the IC die comprises a microprocessor and the platform further comprises a power supply coupled to the IC die

In fourteenth examples, a computer platform comprises an IC die, the IC die package heat exchanger in any of the ninth through eleventh examples, and a thermal interface material (TIM) between the IC die and the IC die package heat exchanger.

In fifteenth examples, for any of the fourteenth examples the IC die comprises a microprocessor and the platform further comprises a power supply coupled to the IC die.

In sixteenth examples, a method of fabricating an IC die heat exchanger comprises receiving a heat pipe, spray depositing a base material onto an exposed surface of the heat pipe, and planarizing a surface of the base material opposite the heat pipe to interface with a surface of an IC die, or a thermal interface material (TIM) thereon.

In seventeenth examples, for any of the sixteenth examples the spray depositing further comprises cold spraying a material having a thermal conductivity of at least 200 Wm⁻¹K⁻¹ to a thickness of at least 100 μm.

In eighteenth examples, for any of the sixteenth through seventeenth examples the spray depositing further comprises propelling one or more powders through a stencil.

In nineteenth examples, a method of fabricating an IC die heat exchanger comprises receiving a heat sink comprising one or more fins, spray depositing a wick material upon a surface of the heat sink, and enclosing the wick material within a heat pipe by bonding a half-open tube to the wick material or to the heat sink.

In twentieth examples, for any of the nineteenth examples bonding the half-open tube comprises soldering or brazing with a filler material.

In twenty-first examples, for any of the nineteenth through twentieth examples the wick material has a different composition or microstructure than the half-open tube or the filler material.

In twenty-second examples, for any of the nineteenth through twenty-first examples the method further comprises spray depositing supplemental material over the heat pipes, the supplemental heat sink material having a thermal conductivity of at least 200 Wm⁻¹K⁻¹.

In twenty-third examples, for any of the nineteenth through twenty-second examples the method comprises spray depositing a second wick material upon a surface of the supplemental heat sink material, and enclosing the second wick material within a second heat pipe by bonding a second half-open tube to the second wick material or to the supplemental heat sink material.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An integrated circuit (IC) die package heat exchanger, comprising:
a heat pipe comprising to contain flows of a vapor and a liquid between a hot interface and a cold interface; and
a base plate contiguous with the hot interface of the heat pipe, wherein the base plate has a substantially planar surface to interface with a surface of an IC die package, and wherein the base plate has a different composition or microstructure than the heat pipe.

2. The IC die package heat exchanger of claim 1, wherein the base plate has a thickness of at least 100 μm.

3. The IC die package heat exchanger of claim 2, wherein the base plate has a thermal conductivity of at least 100 Wm⁻¹K⁻¹.

4. The IC die package heat exchanger of claim 3, wherein the base plate comprises at least one of a metal, silicon, or carbon.

5. The IC die package heat exchanger of claim 3, wherein the base plate has a void area of at least 0.1%.

6. The IC die package heat exchanger of claim 3, wherein the base plate has an RMS surface roughness below 10 μm.

7. The IC die package heat exchanger of claim 1, wherein the heat pipe comprises a wick material that is in direct contact with the base plate.

8. The IC die package heat exchanger of claim 7, wherein the wick material has a thickness of at least 10 μm.

9. An integrated circuit (IC) die package heat exchanger, comprising:
a heat pipe to contain flows of a vapor and a liquid between a hot interface and a cold interface, the heat pipe comprising a wick material; and
a heat sink contiguous with the wick material at the cold interface of the heat pipe, wherein the wick material has a different composition or microstructure than the heat sink.

10. The IC die package heat exchanger of claim 9, wherein the wick material has a thickness of at least 10 μm and a void area of at least 0.1%.

11. The IC die package heat exchanger of claim 9, wherein the heat pipe comprises a half-open tube bonded to the wick material by an intervening filler material, the wick material having a different composition or microstructure than the half-open tube or filler material.

12. A computer platform comprising:
an IC die;
the IC die package heat exchanger of claim 1; and
a thermal interface material (TIM) between the IC die and the base plate.

13. The computer platform of claim 12, wherein the IC die comprises a microprocessor and the platform further comprises a power supply coupled to the IC die.

14. A computer platform comprising:
an IC die;
the IC die package heat exchanger of claim 9; and
a thermal interface material (TIM) between the IC die and the IC die package heat exchanger.

15. The computer platform of claim 14, wherein the IC die comprises a microprocessor and the platform further comprises a power supply coupled to the IC die.

16. A method of fabricating an IC die heat exchanger, the method comprising:
receiving a heat pipe;
spray depositing a base material onto an exposed surface of the heat pipe; and
planarizing a surface of the base material opposite the heat pipe to interface with a surface of an IC die, or a thermal interface material (TIM) thereon.

17. The method of claim 16, wherein the spray depositing further comprises cold spraying a material having a thermal conductivity of at least 200 Wm⁻¹K⁻¹ to a thickness of at least 100 μm.

18. The method of claim 17, wherein the spray depositing further comprises propelling one or more powders through a stencil.

19. A method of fabricating an IC die heat exchanger, the method comprising:
receiving a heat sink comprising one or more fins;
spray depositing a wick material upon a surface of the heat sink; and
enclosing the wick material within a heat pipe by bonding a half-open tube to the wick material or to the heat sink.

20. The method of claim 19, wherein bonding the half-open tube comprises soldering or brazing with a filler material.
